(19) United States
(12) Patent Application Publication
(10) Pub. No.: US 2005/0186754 A1
(43) Pub. Date: Aug. 25, 2005

(54) Solid-state imaging apparatus having multiple anti-reflective layers and method for fabricating the multiple anti-reflective layers

(75) Inventor: Hong-ki Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/065,211

(22) Filed: Feb. 24, 2005

(30) Foreign Application Priority Data
Feb. 25, 2004 (KR) 04-12763

(51) Int. Cl. H01L 21/8238; G03C 5/00; H01L 21/76; H01L 23/544

(52) U.S. Cl. 438/401; 438/200; 257/797

(57) ABSTRACT

A solid-state imaging apparatus comprising multiple anti-reflective layers which can improve a smear characteristic while suppressing a dark defect and a method for fabricating the multiple anti-reflective layers are provided. The solid-state imaging apparatus includes a light receiving unit, a charge transfer unit, and multiple anti-reflective layers. The method includes forming a first anti-reflective layer, forming a second anti-reflective layer, forming a photoresist mask, removing the second anti-reflective layer, and removing the first anti-reflective layer.

This application claims priority from Korean Patent Application No. 10-2004-0012763 filed on Feb. 25, 2004 in the Korean Intellectual Property Office, the contents of which are incorporated herein by reference.

### BACKGROUND OF THE INVENTION

1. Field of the Invention

The present invention relates to a solid-state imaging apparatus having a multiple anti-reflective layers and a method for fabricating the multiple anti-reflective layers, more particularly, to a solid-state imaging apparatus having multiple anti-reflective layers which improve a smear characteristic while suppressing a dark defect, and a method for fabricating the multiple anti-reflective layers.

2. Description of the Related Art

In recent years, attention has focused on a solid-state imaging apparatus for use in camcorders, mobile phones, digital cameras, and so on, as an electronic eye. In general, a solid-state imaging apparatus includes a light receiving element for converting a signal of incident light into an electrical image charge signal, and a charge transfer element for receiving the electrical image charge signal converted by the light receiving element and transferring the same to an output terminal.

With the recent tendency toward smaller, highly functional camcorders, mobile phones, digital cameras and the like, highly integrated, highly functional solid-state imaging apparatuses are increasingly demanded. Accordingly, an area of a solid-state imaging apparatus is gradually reduced, and a light receiving element constituting the solid-state imaging apparatus is also reduced in size. Thus, the light receiving element is becoming less sensitive to incident light.

A conventional solid-state imaging apparatus will now be described with reference to FIGS. 1 through 3. FIG. 1 is a plan view of a conventional solid-state imaging apparatus, FIG. 2 is a cross-section view of the conventional solid-state imaging apparatus taken along the line II-II′ of FIG. 1, and FIG. 3 illustrates reflectivity of light incident to a light receiving element of the conventional solid-state imaging apparatus.

As shown in FIGS. 1 and 2, the conventional solid-state imaging apparatus includes a light receiving element 1 formed on a semiconductor substrate 10, a charge transfer element 2, and a channel stop 3. The light receiving element 1 converts a signal of incident light into an electrical image charge signal. The charge transfer element 2 receives the electrical image signal converted by the light receiving element 1. The channel stop 3 prevents the electrical image signal converted by an adjacent light receiving element from being transferred to the charge transfer element 2. In addition, the conventional solid-state imaging apparatus includes a gate insulating layer 30 formed on the semiconductor substrate 10 having an area where the light receiving element 1 and the charge transfer element 2 are formed, a signal electrode 40 formed on the gate insulating layer 30 excluding an area where the light receiving element 1 is formed, and a shading layer 50 formed on the gate insulating layer 30 excluding an area where the light receiving element 1 is formed, the shading layer 50 preventing incident light from being induced into the charge transfer element 2.

As shown in FIG. 3, in the case where the semiconductor substrate 10 is made of silicon (Si) and the gate insulating layer 30 is made of silicon oxide (SiO₂), if visible light having a predetermined incidence angle Φ0 (wavelength in a range of 400˜700 nm) is incident into the semiconductor substrate 10, approximately 20 to 30% of the incident light is reflected from the semiconductor substrate 10 having the light receiving element 1, so that the amount of light incident to the light receiving element 1 is reduced, thereby making the light receiving element 1 less sensitive to the incident light signal.

To address this problem, an anti-reflective layer may be formed on the semiconductor substrate 10 having the light receiving element 1 to reduce reflection of light. The shading layer 50 is preferably formed of a metallic substance after forming the anti-reflective layer. If the anti-reflective layer is first formed on the entire surface of the semiconductor substrate 10 having the light receiving element 1 and the charge transfer element 2 and the shading layer 50 is then formed thereon, a thickness of a layer underlying the shading layer 50 undesirably increases, which may generate an erroneous image charge signal due to diffused reflection of light incident to a portion surrounding the light receiving element 1, and cause noise, thereby resulting in a deterioration in smear components.

This problem can be solved by selectively removing the anti-reflective layer in an area other than the area where the light receiving element 1 is formed. However, when the anti-reflective layer is selectively removed by dry etching, damage may occur to the semiconductor substrate 10 due to plasma generated during dry etching. Accordingly, a dark defect phenomenon may appear due to such plasma damage.

Korean Patent Application Publication No. 1998-0080644 discloses a solid-state imaging apparatus having a micro lens in a light receiving element, and an anti-reflective layer on the micro lens, the anti-reflective layer having a refractive index smaller than that of the micro lens, for preventing incident light from being reflected by the anti-reflective layer, thereby increasing the amount of light incident to the light receiving element. However, the disclosed solid-state imaging apparatus will have different smear components depending on a distance between the micro lens and the light receiving element. Thus, it is quite difficult to uniformly control smearing characteristics occurring in multiple light receiving elements.

### SUMMARY OF THE INVENTION

The present invention provides a solid-state imaging apparatus comprising multiple anti-reflective layers which can improve a smear characteristic while suppressing a dark defect.

The present invention also provides a method for fabricating the multiple anti-reflective layers of a solid-state imaging apparatus, which can improve a smear characteristic while suppressing a dark defect.

According to an aspect of the present invention, there is provided a solid-state imaging apparatus comprising: a light receiving unit formed on a semiconductor substrate for converting a signal of incident light into an electrical image charge signal, a charge transfer unit formed on the semiconductor substrate for receiving the electrical image charge signal converted by the light receiving unit, and multiple anti-reflective layers formed on the light receiving unit for reducing reflection of the signal of incident light, wherein the multiple anti-reflective layers include a first anti-reflective layer having a refractive index smaller than that of the semiconductor substrate and a second anti-reflective layer formed on the first anti-reflective layer having a refractive index smaller than that of the first anti-reflective layer.

In one embodiment, the thickness of the first anti-reflective layer is in a range of 10˜1000 Å. The thickness of the second anti-reflective layer can be in a range of 10˜1000 Å.

In one embodiment, the first anti-reflective layer is formed of silicon nitride (Si₃N₄), and the second anti-reflective layer is formed of silicon oxide (SiO2). In one embodiment, the first anti-reflective layer is formed of silicon oxynitride (SiON), and the second anti-reflective layer is formed of silicon oxide (SiO2).

In one embodiment, the multiple anti-reflective layers include a third anti-reflective layer formed between the light receiving unit and the first anti-reflective layer and having a refractive index smaller than that of the first anti-reflective layer. In one embodiment, the thickness of the third anti-reflective layer is in a range of 10 to 500 Å. In one embodiment, the third anti-reflective layer is formed of silicon oxide (SiO₂).

According to another aspect of the present invention, there is provided a method for fabricating multiple anti-reflective layers of a solid-state imaging apparatus comprising: (i) forming a first anti-reflective layer on a semiconductor substrate having a light receiving unit which converts a signal of incident light into an electrical image charge signal and a charge transfer unit which receives the electrical image charge signal converted by the light receiving unit, the first anti-reflective layer having a refractive index smaller than that of the semiconductor substrate, (ii) forming a second anti-reflective layer on the first anti-reflective layer, the second anti-reflective layer having a refractive index smaller than that of the first anti-reflective layer, (iii) forming a photoresist mask on the second anti-reflective layer facing an area having the light receiving unit, (iv) removing the second anti-reflective layer excluding an area having the photoresist mask, and (v) removing the first anti-reflective layer excluding an area having the second anti-reflective layer, thereby completing the multiple anti-reflective layers on the light receiving unit.

In one embodiment, the first anti-reflective layer is formed to a thickness in a range of 10 to 1000 Å. In one embodiment, the second anti-reflective layer is formed to a thickness in a range of 10 to 1000 Å. In one embodiment, the first anti-reflective layer is made of silicon nitride (Si₃N₄), and the second anti-reflective layer is made of silicon oxide (SiO₂). In one embodiment, the second anti-reflective layer is removed by wet etching. In one embodiment, the second anti-reflective layer is removed by wet etching using a mixed solution of NH₄F, H₂O, and HF.

In one embodiment, the first anti-reflective layer is removed by wet etching. In one embodiment, the first anti-reflective layer is removed by wet etching using a H₃PO₄ solution.

In one embodiment, the first anti-reflective layer is made of silicon oxynitride (SiON), and the second anti-reflective layer is made of silicon oxide (SiO₂). In one embodiment, the second anti-reflective layer is removed by wet etching. In one embodiment, the second anti-reflective layer is removed by wet etching using a mixed solution of NH₄F, H₂O, and HF. In one embodiment, the first anti-reflective layer is removed by wet etching. In one embodiment, the first anti-reflective layer is removed by wet etching using a H₃PO₄ solution.

In one embodiment, the method further comprises forming a third anti-reflective layer having a refractive index smaller than that of the first anti-reflective layer on the semiconductor substrate, the forming of the third anti-reflective layer being followed by forming the first anti-reflective layer. In one embodiment, the third anti-reflective layer is formed to a thickness in a range of 10 to 500 Å. In one embodiment, the third anti-reflective layer is made of silicon oxide (SiO2).

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thicknesses of layers are exaggerated for clarity.

FIG. 1 is a plan view of a conventional solid-state imaging apparatus.

FIG. 2 is a cross-section view of the conventional solid-state imaging apparatus taken along the line II-II′ of FIG. 1.

FIG. 3 illustrates reflectivity of light incident to a light receiving element of the conventional solid-state imaging apparatus.

FIG. 4 is a cross-sectional view of a solid-state imaging apparatus according to an embodiment of the present invention.

FIG. 5 is a flowchart illustrating a method for fabricating multiple anti-reflective layers of the solid-state imaging apparatus according to the present invention.

FIG. 6A through FIG. 6F are cross-sectional views showing the method for fabricating the multiple anti-reflective layers of a solid-state imaging apparatus according to the present invention.

FIG. 7 is a cross-sectional view showing a method for fabricating multiple anti-reflective layers of a solid-state imaging apparatus according to another embodiment of the present invention.

FIGS. 8A through 8F are cross-sectional views showing the method for fabricating the multiple anti-reflective layers of the solid-state imaging apparatus according to another embodiment of the present invention.

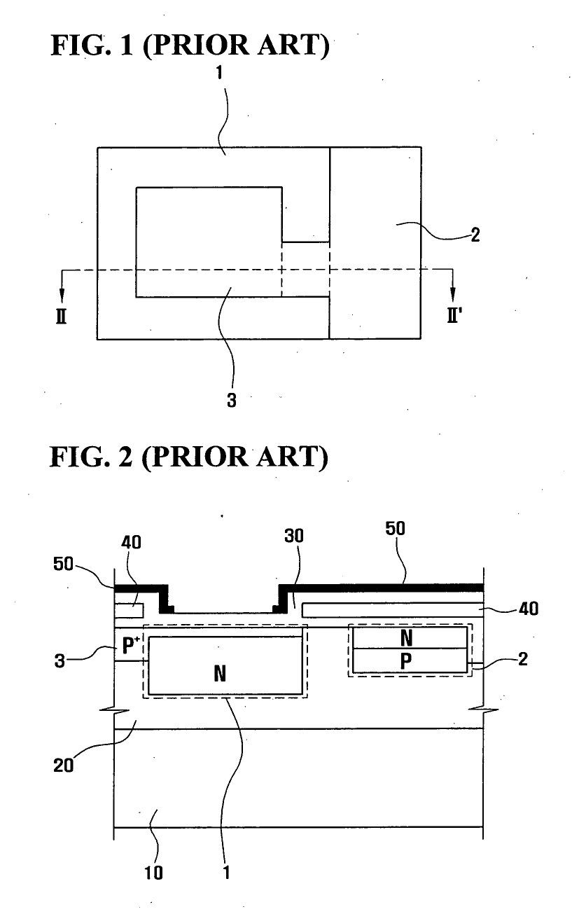

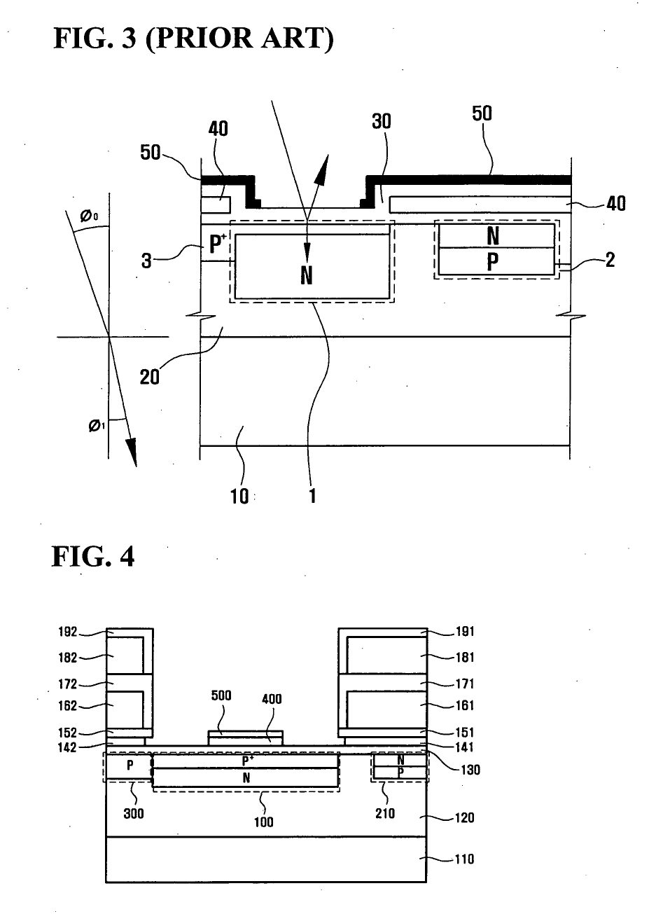

### DETAILED DESCRIPTION OF PREFERRED EMBODIMENTS

In the following detailed description, whenever a layer or structure is referred to as “on” another layer or structure, the first layer or structure may be directly on the second layer or structure, or other intervening layers or structures may be present.

Referring to FIGS. 4, 5, and 6A through 6F, a solid-state imaging apparatus comprising multiple anti-reflective layers according to the present invention, which has improved smear correction capability while suppressing dark defects, will now be described.

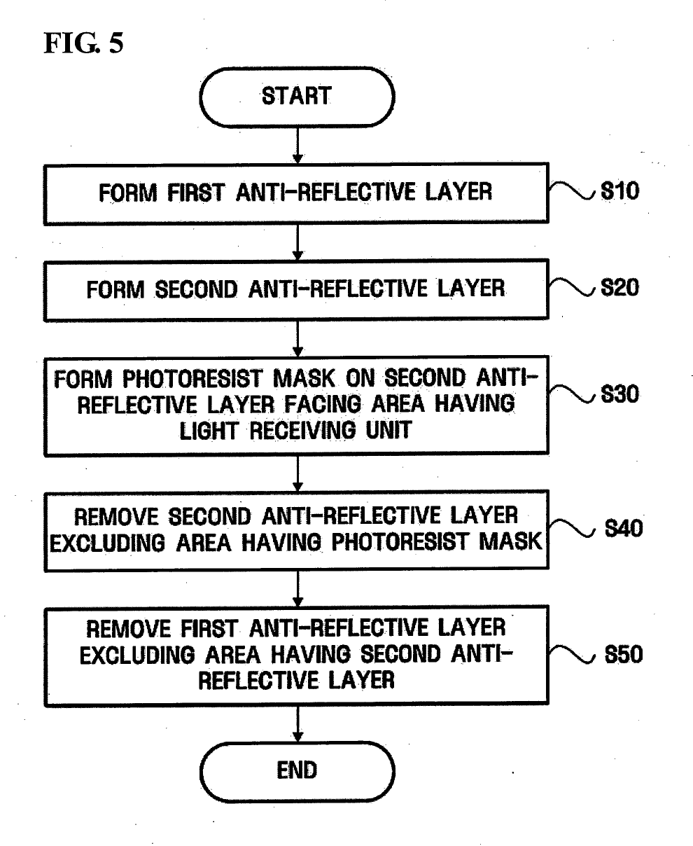

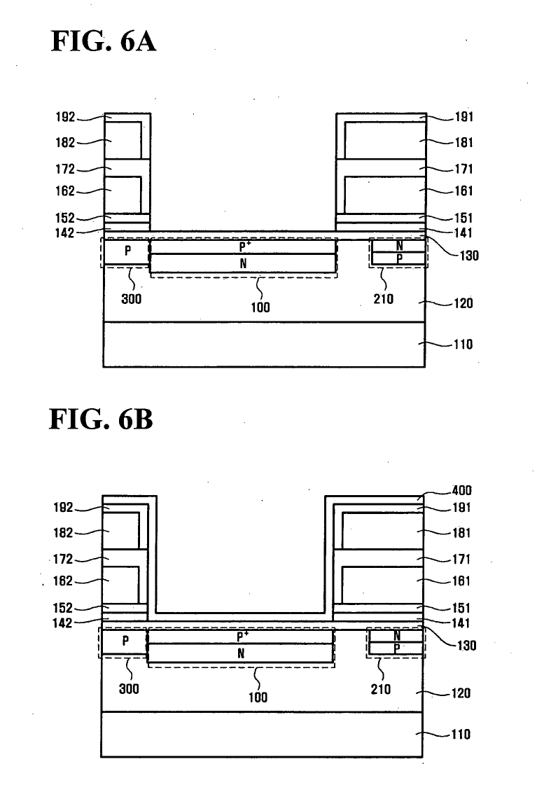

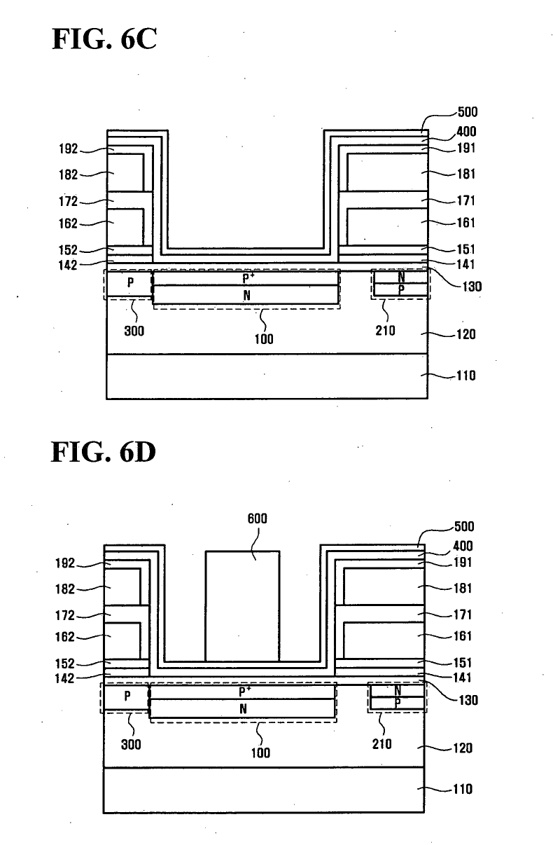

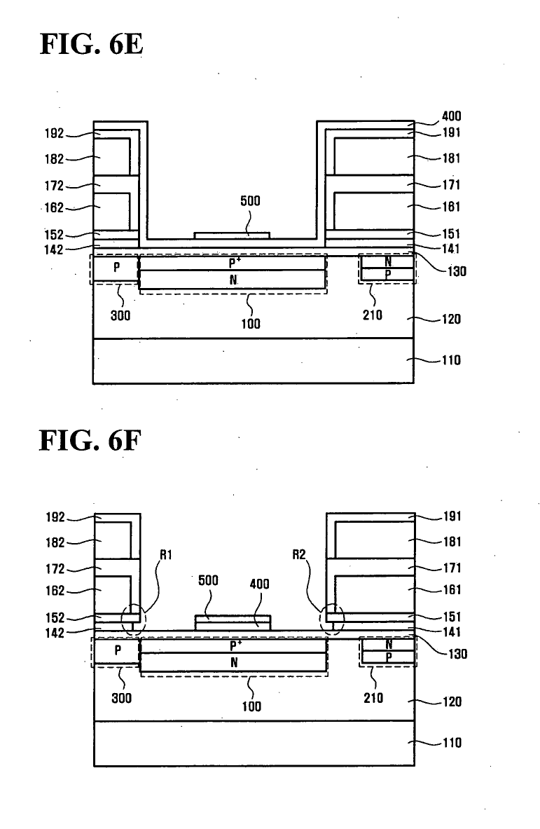

FIG. 4 is a cross-sectional view of a solid-state imaging apparatus according to an embodiment of the present invention, FIG. 5 is a flowchart illustrating a method for fabricating multiple anti-reflective layers of the solid-state imaging apparatus according to the present invention, and FIG. 6A through FIG. 6F are cross-sectional views showing the method for fabricating the multiple anti-reflective layers of solid-state imaging apparatus according to the present invention.

The solid-state imaging apparatus according to an embodiment of the present invention, as shown in FIG. 4, includes a light receiving unit 100, a charge transfer unit 210, and multiple anti-reflective layers. The light receiving unit 100 formed on a semiconductor substrate 110, converts a signal of incident light into an electrical image charge signal. The charge transfer unit 210 formed on the semiconductor substrate 110 and receives the electrical image charge signal converted by the light receiving unit 100. The multiple anti-reflective layers formed on the light receiving unit 100 substantially reduce or prevent reflection of the signal of incident light and include a first anti-reflective layer 400 having a refractive index smaller than that of the semiconductor substrate 110 and a second anti-reflective layer 500 formed on the first anti-reflective layer 400 and having a refractive index smaller than that of the first anti-reflective layer 400.

Here, the semiconductor substrate 110 is an n type silicon substrate, and has a p type well 120 formed thereon. A photodiode consisting of an n type area and a p type area is formed in the p type well 120. The photodiode corresponds to the light receiving unit 100. A charge coupled device consisting of an n type area and a p type area is also formed in the p type well 120 to be spaced a predetermined distance from the light receiving unit 100. The charge coupled device corresponds to a charge transfer unit 210 and has a channel stop 300 for preventing the electrical image charge signal converted by the light receiving unit 100 from being transferred to other adjacent charge transfer units.

A first gate insulating layer 130 made of silicon oxide (SiO₂) is formed over the entire surface of the semiconductor substrate 110. Second gate insulating layers 141 and 142 made of silicon nitride (Si₃N₄) are formed on the first gate insulating layer 130 facing an area having the charge transfer unit 210. Third gate insulating layers 151 and 152 made of silicon oxide (SiO₂) are formed on the second gate insulating layers 141 and 142. In addition, first signal electrodes 161 and 162 made of polysilicon are formed on the third gate insulating layers 151 and 152, and interlayer insulators 171 and 172 made of silicon oxide (SiO₂) are formed on the first signal electrodes 161 and 162. Second signal electrodes 181 and 182 made of polysilicon are formed on the interlayer insulators 171 and 172, and fourth gate insulating layers 191 and 192 made of silicon oxide (SiO₂) are formed on the second signal electrodes 181 and 182. Voltage signals are applied to the first signal electrodes 161 and 162 or the second signal electrodes 181 and 182 to transfer the electrical image charge signal converted by the light receiving unit 100 to the charge transfer unit 210.

The solid-state imaging apparatus according to an embodiment of the present invention includes multiple anti-reflective layers, including the first anti-reflective layer 400 having a refractive index smaller than that of the semiconductor substrate 110 and the second anti-reflective layer 500 having a refractive index smaller than that of the first anti-reflective layer 400, on the light receiving unit 100, thereby reducing reflection of incident light at the portion of the semiconductor substrate 110 having the light receiving unit 100, that is, increasing the amount of light incident into the light receiving unit 100. In such a manner, the sensitivity characteristic of the light receiving unit 100 with respect to the incident light can be improved. In addition, the multiple anti-reflective layers formed on the area having the light receiving unit 100 suppress diffused reflection of light incident into an area surrounding the light receiving unit 100, thereby improving the smear characteristic. The refractive index of the first anti-reflective layer 400 is preferably larger than that of the first gate insulating layer 130, which allows the incident light to be more efficiently converged into the light receiving unit 100.

The thickness of the first anti-reflective layer 400 is preferably in a range of approximately 10 to approximately 1000 Å. If the first anti-reflective layer 400 is excessively thick, the reflectivity of the first anti-reflective layer 400 may overly increase, causing a reduction in the sensitivity of the light receiving unit 100. The thickness of the second anti-reflective layer 500 is preferably in a range of approximately 10 to approximately 1000 Å. If the second anti-reflective layer 500 is excessively thick, the reflectivity of the second anti-reflective layer 500 may also overly increase, so that the sensitivity of the light receiving unit 100 may decrease, as in the case of the first anti-reflective layer 400.

In one embodiment, the first anti-reflective layer 400 is formed of a silicon nitride (Si₃N₄) film, and the second anti-reflective layer 500 is formed of a silicon oxide (SiO₂) film. When a silicon substrate is used as the semiconductor substrate 110, the refractive index of the silicon substrate 110 ranges from approximately 3 to approximately 5. The refractive index of the silicon nitride (Si₃N₄) film is approximately 2.0, and the refractive index of the silicon oxide (SiO₂) film is approximately 1.45. Thus, the silicon nitride (Si₃N₄) film can be used as the first anti-reflective layer 400, and the silicon oxide (SiO₂) film can be used as the second anti-reflective layer 500. The silicon nitride film that is useful as the first anti-reflective layer 400 can be formed by low pressure chemical vapor deposition (LPCVD), and the silicon oxide film that is useful as the second anti-reflective layer 500 can also be formed by LPCVD.

In another embodiment, the first anti-reflective layer 400 is formed of a silicon oxynitride (SiON) film, and the second anti-reflective layer 500 is formed of a silicon oxide (SiO₂) film. When a silicon substrate is used as the semiconductor substrate 110, the refractive index of the silicon substrate 110 ranges from approximately 3 to approximately 5, the refractive index of the silicon oxynitride (SiON) film is approximately 2.63, and the refractive index of the silicon oxide (SiO₂) film is approximately 1.45. Thus, the silicon oxynitride (SiON) film can be used as the first anti-reflective layer 400 and the silicon oxide (SiO₂) film can be used as the second anti-reflective layer 500. The silicon oxynitride film that is useful as the first anti-reflective layer 400 can be formed by LPCVD, and the silicon oxide film that is useful as the second anti-reflective layer 500 can also be formed by LPCVD.

The method for fabricating multiple anti-reflective layers of a solid-state imaging apparatus according to the present invention includes forming the first anti-reflective layer 400 in step S10, forming the second anti-reflective layer 500 in step S20, and forming a photoresist mask pattern 600 on the second anti-reflective layer facing the area having the light receiving unit in step S30. In step S40, the second anti-reflective layer 500 is removed, except in the area having the photoresist mask. In step S50, the first anti-reflective layer 400 is removed, except in the area having the first anti-reflective layer.

As shown in FIG. 6A, a p type well 120 is formed in the semiconductor substrate 110. A photodiode having an n type area and a p type area is formed in the p type well 120. The photodiode corresponds to the light receiving unit 100. A charge coupled device having an n type area and a p type area is also formed in the p type well 120 to be spaced a predetermined distance from the light receiving unit 100. The charge coupled device corresponds to a charge transfer unit 210 and has a channel stop 300 for preventing the electrical image charge signal converted by the light receiving unit 100 from being transferred to other adjacent charge transfer units.

A first gate insulating layer 130 is formed over the entire surface of the semiconductor substrate 110 using silicon oxide (SiO₂). Second gate insulating layers 141 and 142 made of silicon nitride (Si₃N₄) are formed on the first gate insulating layer 130 facing an area having the charge transfer unit 210. Third gate insulating layers 151 and 152 made of silicon oxide (SiO₂) are formed on the second gate insulating layers 141 and 142. In addition, first signal electrodes 161 and 162 made of polysilicon are formed on the third gate insulating layers 151 and 152, and interlayer insulators 171 and 172 made of silicon oxide (SiO₂) are formed on the first signal electrodes 161 and 162. Second signal electrodes 181 and 182 made of polysilicon are formed on the interlayer insulators 171 and 172, and fourth gate insulating layers 191 and 192 made of silicon oxide (SiO₂) are formed on the second signal electrodes 181 and 182.

As shown in FIG. 6B, a first anti-reflective layer 400 having a refractive index smaller than that of the semiconductor substrate 110 is formed on the on the semiconductor substrate 110. As described above, the first anti-reflective layer 400 is formed to a thickness in a range of approximately 10 to approximately 1000 Å, and the first anti-reflective layer 400 can be made of a silicon nitride film or a silicon oxynitride film, which can be formed by low pressure chemical vapor deposition (LPCVD).

As shown in FIG. 6C, a second anti-reflective layer 500 having a refractive index smaller than that of the first anti-reflective layer 400 is formed on the first anti-reflective layer 400. As above described, the second anti-reflective layer 500 is preferably formed to a thickness in a range of approximately 10 to approximately 1000 Å, and the second anti-reflective layer 400 can be made of a silicon oxide film, which may be either middle temperature oxide (MTO) formed at a temperature in a range of approximately 700° C. to approximately 770° C. or high temperature oxide (HTO) formed at a temperature in a range of approximately 770° C. to approximately 850° C., by LPCVD.

Next, as shown in FIG. 6D, a photoresist mask is formed on the second anti-reflective layer 500 facing an area having the light receiving unit 100. The photoresist mask 600 can be used as a protective layer for removing the second anti-reflective layer 500 excluding an area having the light receiving unit 100 in a subsequent process for forming multiple anti-reflective layers only on an area having the light receiving unit 100.

Then, as shown in FIG. 6E, the second anti-reflective layer 500 is removed excluding an area having the photoresist mask 600. The second anti-reflective layer 500 is preferably removed by wet etching. By doing so, plasma damage, which may be caused during dry etching, can be removed from the semiconductor substrate 10, thereby effectively suppressing a dark defect. In a case where a silicon oxide film is used as the second anti-reflective layer 500, the silicon oxide film is selectively etched using a mixed solution of NH₄F, H₂O, and HF.

As shown in FIG. 6F, the first anti-reflective layer 400 is removed excluding an area having the second anti-reflective layer 500. As described above, in order to effectively suppress generation of a dark defect, the first anti-reflective layer 400 is preferably removed by wet etching. Here, the second anti-reflective layer 500 is used as a protective layer for removing the first anti-reflective layer 400 excluding an area having the light receiving unit 100. In a case where a silicon nitride film is used as the first anti-reflective layer 400, the silicon nitride film is selectively etched using a H₃PO₄ solution. In a case where a silicon oxynitride film is used as the first anti-reflective layer 400, the silicon oxynitride film is selectively etched using a mixed solution of H₂O₂, H₂O, and HF.

Alternatively, the first anti-reflective layer 400 and the second anti-reflective layer 500 may also be prepared by forming the first anti-reflective layer 400, removing the first anti-reflective layer 400 excluding an area having the light receiving unit 100, forming the second anti-reflective layer 500, and removing the second anti-reflective layer 500 excluding an area having the light receiving unit 100.

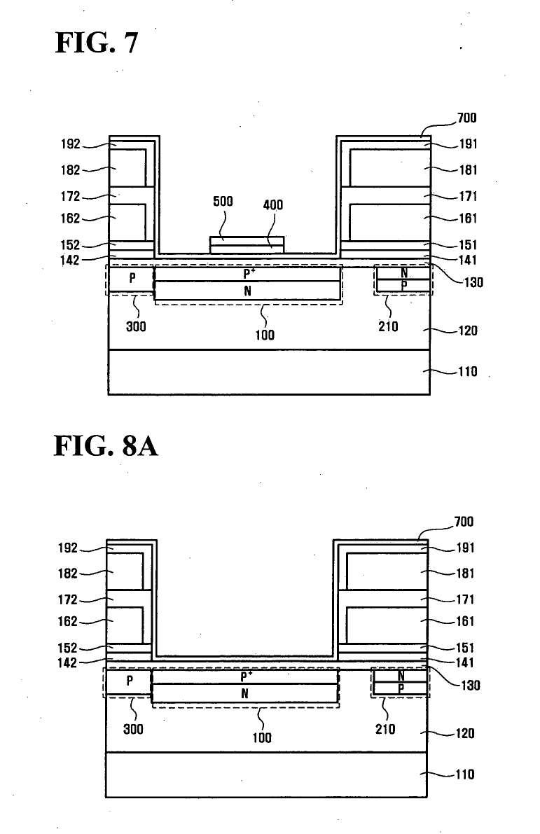

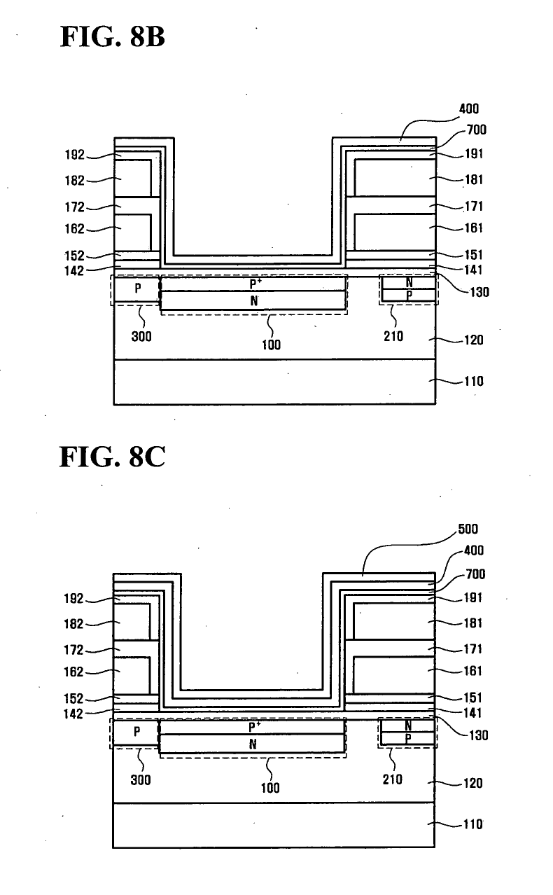

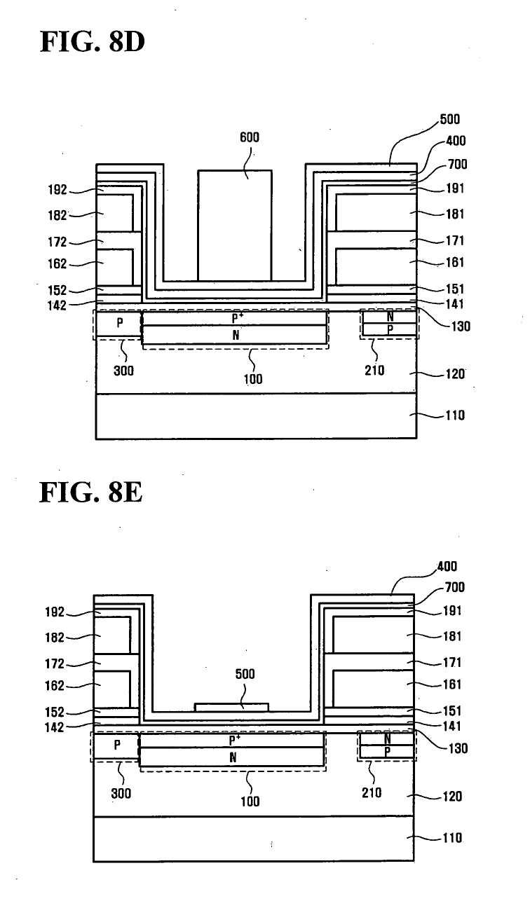

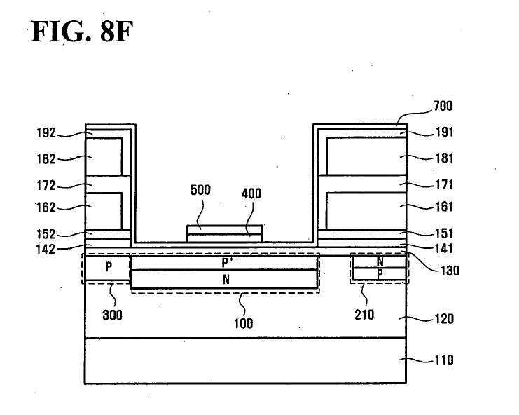

Referring to FIGS. 7 and 8A through 8F, a solid-state imaging apparatus having multiple anti-reflective layers according to another embodiment of the present invention and a method for fabricating the multiple anti-reflective layers will now be described. FIG. 7 is a cross-sectional view showing a method for fabricating multiple anti-reflective layers of a solid-state imaging apparatus according to another embodiment of the present invention, and FIGS. 8A through 8F are cross-sectional views showing the method for fabricating the multiple anti-reflective layers of the solid-state imaging apparatus according to another embodiment of the present invention. The embodiment of FIGS. 7 and 8A through 8F is the same as that of FIGS. 4, 5 and 6A through 6F, except for the presence of a third anti-reflective layer as described below.

As shown in FIG. 7, the solid-state imaging apparatus according to another embodiment of the present invention further includes a third anti-reflective layer 700 formed over the entire surface of the semiconductor substrate 110 including an area having the light receiving unit 100 and an area having the charge transfer unit 210 between the light receiving unit 100 and the first anti-reflective layer 400, the third anti-reflective layer 700 having a refractive index smaller than that of the first anti-reflective layer 400. When a silicon nitride film is used as the first anti-reflective layer 400, wet etching of the first anti-reflective layer 400 excluding an area having the light receiving unit 100 may cause damage to lateral surfaces R1 and R2 of the second gate insulating layers 141 and 142 made of silicon nitride due to an isotropic property of the wet etching, as shown in FIG. 6F. Such damage occurring to the lateral surfaces of the second gate insulating layers 141 and 142 can be prevented by forming the third anti-reflective layer 700. The third anti-reflective layer 700 is preferably formed of silicon oxide, which is the same material as the first gate insulating layer 130, to a thickness of approximately 10 to approximately 500 Å. If the third anti-reflective layer 700 is excessively thick, the reflectivity of the third anti-reflective layer 700 may overly increase, causing a reduction in the sensitivity of the light receiving unit 100.

According to another embodiment of the present invention, the method for fabricating multiple anti-reflective layers further comprises forming a third anti-reflective layer 700 over the entire surface of the semiconductor substrate 110 prior to forming the first anti-reflective layer 400.

The thickness of the third anti-reflective layer 700 is in a range of approximately 10 to approximately 500 Å. The third anti-reflective layer 700 may be formed of silicon oxide (SiO₂). The silicon oxide may be either MTO formed at a temperature in a range of approximately 700° C. to approximately 770° C. or HTO formed at a temperature in a range of approximately 770° C. to approximately 850° C., by LPCVD.

While the present invention has been particularly shown and described with respect to illustrative embodiments thereof, it will be understood by those skilled in the art that the foregoing and other changes in form and details may be made therein without departing from the spirit and scope of the invention which should be limited only by the scope of the appended claims.

As described above, the present invention provides a solid-state imaging apparatus including multiple anti-reflective layers which can improve a smear characteristic while suppressing a dark defect, and a method for fabricating the multiple anti-reflective layers.

1. A solid-state imaging apparatus comprising:
a light receiving unit formed on a semiconductor substrate for converting a signal of incident light into an electrical image charge signal;
a charge transfer unit formed on the semiconductor substrate for receiving the electrical image charge signal converted by the light receiving unit; and
multiple anti-reflective layers formed on the light receiving unit for reducing reflection of the signal of incident light,
wherein the multiple anti-reflective layers include a first anti-reflective layer having a refractive index smaller than that of the semiconductor substrate and a second anti-reflective layer formed on the first anti-reflective layer and having a refractive index smaller than that of the first anti-reflective layer.

2. The solid-state imaging apparatus of claim 1, wherein the thickness of the first anti-reflective layer is in a range of 10˜1000 Å.

3. The solid-state imaging apparatus of claim 1, wherein the thickness of the second anti-reflective layer is in a range of 10˜1000 Å.

4. The solid-state imaging apparatus of claim 1, wherein the first anti-reflective layer is formed of silicon nitride (Si₃N₄), and the second anti-reflective layer is formed of silicon oxide (SiO2).

5. The solid-state imaging apparatus of claim 1, wherein the first anti-reflective layer is formed of silicon oxynitride (SiON), and the second anti-reflective layer is formed of silicon oxide (SiO2).

6. The solid-state imaging apparatus of claim 1, wherein the multiple anti-reflective layers include a third anti-reflective layer formed between the light receiving unit and the first anti-reflective layer and having a refractive index smaller than that of the first anti-reflective layer.

7. The solid-state imaging apparatus of claim 6, wherein the thickness of the third anti-reflective layer is in a range of 10 to 500 Å.

8. The solid-state imaging apparatus of claim 6, wherein the third anti-reflective layer is formed of silicon oxide (SiO₂).

9. A method for fabricating multiple anti-reflective layers of a solid-state imaging apparatus comprising:
forming a first anti-reflective layer on a semiconductor substrate having a light receiving unit for converting a signal of incident light into an electrical image charge signal and a charge transfer unit which receives the electrical image charge signal converted by the light receiving unit, the first anti-reflective layer having a refractive index smaller than that of the semiconductor substrate;
forming a second anti-reflective layer on the first anti-reflective layer, the second anti-reflective layer having a refractive index smaller than that of the first anti-reflective layer;
forming a photoresist mask on the second anti-reflective layer facing an area having the light receiving unit;
removing the second anti-reflective layer excluding an area having the photoresist mask; and
removing the first anti-reflective layer excluding an area having the second anti-reflective layer.

10. The method of claim 9, wherein the first anti-reflective layer is formed to a thickness in a range of 10 to 1000 Å.

11. The method of claim 9, wherein the second anti-reflective layer is formed to a thickness in a range of 10 to 1000 Å.

12. The method of claim 9, wherein the first anti-reflective layer is made of silicon nitride (Si₃N₄), and the second anti-reflective layer is made of silicon oxide (SiO₂).

13. The method of claim 12, wherein the second anti-reflective layer is removed by wet etching.

14. The method of claim 13, wherein the second anti-reflective layer is removed by wet etching using a mixed solution of NH₄F, H₂O, and HF.

15. The method of claim 12, wherein the first anti-reflective layer is removed by wet etching.

16. The method of claim 15, wherein the first anti-reflective layer is removed by wet etching using a H₃PO₄ solution.

17. The method of claim 9, wherein the first anti-reflective layer is made of silicon oxynitride (SiON), and the second anti-reflective layer is made of silicon oxide (SiO₂).

18. The method of claim 17, wherein the second anti-reflective layer is removed by wet etching.

19. The method of claim 18, wherein the second anti-reflective layer is removed by wet etching using a mixed solution of NH₄F, H₂O, and HF.

20. The method of claim 17, wherein the first anti-reflective layer is removed by wet etching.

21. The method of claim 20, wherein the first anti-reflective layer is removed by wet etching using a H₃PO₄ solution.

22. The method of claim 9, further comprising forming a third anti-reflective layer having a refractive index smaller than that of the first anti-reflective layer on the semiconductor substrate, the forming of the third anti-reflective layer being followed by forming the first anti-reflective layer.

23. The method of claim 22, wherein the third anti-reflective layer is formed to a thickness in a range of 10 to 500 Å.

24. The method of claim 22, wherein the third anti-reflective layer is made of silicon oxide (SiO2).
